(19) United States
(12) Patent Application Publication
(10) Pub. No.: US 2013/0063143 A1
(43) Pub. Date: Mar. 14, 2013

(54) Local SAR Constrained Parallel Transmission RF Pulse in Magnetic Resonance Imaging

(71) Applicants: Elfar Adalsteinsson, Belmont, MA (US); Matthias Gebhardt, Erlangen (DE); Joonsung Lee, Seoul (KR); Lawrence L. Wald, Cambridge, MA (US)

(72) Inventors: Elfar Adalsteinsson, Belmont, MA (US); Matthias Gebhardt, Erlangen (DE); Joonsung Lee, Seoul (KR); Lawrence L. Wald, Cambridge, MA (US)

(73) Assignee: Siemens Aktiengesellschaft, Munchen (DE)

(21) Appl. No.: 13/601,385

(22) Filed: Aug. 31, 2012

Related U.S. Application Data
(60) Provisional application No. 61/530,266, filed on Sep. 1, 2011.

(51) Int. Cl. G01R 33/48; G06F 17/10

(52) U.S. Cl. 324/307; 703/2

(57) ABSTRACT

A method of designing a parallel transmission radio frequency (RF) pulse for a magnetic resonance imaging (MRI) system includes compressing a model for a subject to be scanned by the MRI system into a plurality of virtual observation points within the model based on comparisons of peak sensitivity to local specific absorption rate (SAR), and defining the parallel transmission RF pulse that minimizes a weighted average of local SAR values with an iterative procedure that optimizes a set of weighting factors for the plurality of virtual observation points to maximize the minimized weighted average.

### CROSS-REFERENCE TO RELATED APPLICATION

This application claims the benefit of U.S. provisional application entitled “Local SAR in Parallel Transmission Pulse Design,” filed Sep. 1, 2011, and assigned Ser. No. 61/530,266, the entire disclosure of which is hereby expressly incorporated by reference.

### STATEMENT REGARDING FEDERALLY SPONSORED RESEARCH OR DEVELOPMENT

This invention was made with government support under Research Grant Program (R01) Contract Nos. EB007942 and EB006847 awarded by the National Institutes of Health (NIH). The government has certain rights in the invention.

### FIELD

The disclosure relates generally to magnetic resonance imaging (MRI) systems and, more particularly, to parallel transmission RF pulses for use in MRI systems.

### BACKGROUND

Magnetic resonance imaging (MRI) is a medical imaging technique in widespread use for viewing the structure and function of the human body. MRI systems provide soft-tissue contrast, such as for diagnosing many soft-tissue disorders. MRI systems generally implement a two-phase method. The first phase is the excitation phase, in which a magnetic resonance signal is created in the subject with a main, polarizing magnetic field, B₀, and a radio frequency (RF) excitation pulse, B₁⁺. The second phase is the acquisition phase, in which the system receives an electromagnetic signal emitted as the excited nuclei relax back into alignment with the main magnetic field after the excitation pulse B₁ is terminated. These two phases are repeated pair-wise to acquire enough data to construct an image.

Higher magnetic field strength scanners have been recently used to improve image signal-to-noise ratio and contrast. However, a spatial variation in the magnitude of the RF excitation magnetic field, B₁⁺, occurs with main magnetic field strengths of, for example, 7 Tesla. This undesirable non-uniformity in the excitation across the region of interest is commonly referred to as “center brightening,” “B₁⁺ inhomogeneity” or “flip angle inhomogeneity.”

Newer-generation MRI systems have generated RF pulses with a spatially tailored excitation pattern to mitigate B₁⁺ inhomogeneity by exciting a spatial inverse of the inhomogeneity. In these systems, multiple radio-frequency pulse trains are transmitted in parallel over independent radio-frequency transmit channels, e.g., the individual rods of a whole-body antenna. This method, referred to as “parallel transmission” or “parallel excitation,” exploits variations among the different spatial profiles of a multi-element RF coil array. Parallel excitation has enabled several important applications beyond the mitigation of B₁⁺ inhomogeneity, including flexibly shaped excitation volumes.

Unfortunately, parallel transmission techniques generally increase peak pulse power, giving rise to concerns regarding excessive exposure to RF energy. A typical measure of the physiological absorption of the RF energy is the specific absorption rate, or SAR, which specifies the deposited power per unit weight (watts/kg) due to the RF pulse. Maximum values for SAR are specified by safety regulations and should be met both globally (e.g., power absorbed by the whole head or whole body) and locally (e.g., power absorbed per 10 grams of tissue). For example, a standardized limit of 4 watts/kg applies to the global SAR of a patient according to an IEC (International Electrotechnical Commission) standard.

When multiple transmit channels are simultaneously employed, the local electric fields generated by each channel undergo local superposition, and local extremes in electric field magnitude may arise, leading to spikes in local SAR. Recent studies have confirmed the presence of “hot spots” and found that parallel transmitted pulses produce relatively high ratios of local to whole-head average SAR, as is described by, for example, F. Seifert et al., in “Patient Safety Concept for Multichannel Transmit Coils,” J. Magn. Reson. Imag., 26:1315-1321 (2007). These relatively-high ratios of local to whole-head average SAR make local SAR the limiting factor of parallel transmission MRI. Concerns regarding elevated SAR levels are also set forth in U. Katscher and P. Bornert in “Parallel RF Transmission in MRI.” NMR Biomed, 19:393-400 (2006).

One technique for SAR reduction involves placing constraints on global and local SAR. In this method, SAR constraints are explicitly built into the pulse design process. Because both whole-head mean SAR and local N-gram SAR at any location can be expressed quadratically in terms of pulse sample values, constraints on both whole-head and local SAR can be incorporated simply by adding quadratic constraints to the design method. For example, the method described by I. Graesslin, et al., in “A Minimum SAR RF Pulse Design Approach for Parallel Tx with Local Hot Spot Suppression and Exact Fidelity Constraint,” Proc. Intl. Soc. Magn. Reson. Med., 2008; 612, explicitly accounts for global SAR as well as local SAR at several spatial locations by incorporating several quadratic constraints into the design. However, this approach presents a computationally intractable problem of solving a system of equations with tens of thousands (or millions) of quadratic constraints.

### SUMMARY

Parallel transmission pulses are designed based on spatial sensitivity to local specific absorption rate (SAR) and a minimized weighted average of local SAR values. The spatial sensitivity to local SAR is used to compress a model into a set of virtual observation points. The minimized weighted average of local SAR is then calculated over the virtual observation points in an iterative procedure to optimize a set of weighting factors.

In accordance with one aspect, a method of designing a parallel transmission radio frequency (RF) pulse for a magnetic resonance imaging (MRI) system includes compressing a model for a subject to be scanned by the MRI system into a plurality of virtual observation points within the model based on comparisons of peak sensitivity to local specific absorption rate (SAR), and defining, with a processor, the parallel transmission RF pulse for antenna of the MRI system that minimizes a weighted average of local SAR values with an iterative procedure that optimizes a set of weighting factors for the plurality of virtual observation points to maximize the minimized weighted average.

In accordance with another aspect, a method of imaging with a parallel transmission RF pulse for an MRI system. The parallel transmission RF pulse is transmitted. The parallel transmission RF pulse corresponds a design using a spatial matrix for each voxel of a model for a subject to be scanned by the MRI system where the spatial matrix is indicative of absorption sensitivity, designating a subset of the voxels as a plurality of virtual observation points for the model by iteratively evaluating the spatial matrices of the voxels to determine whether the absorption sensitivity of a respective one of the voxels is upper bounded by a global SAR-based overestimation of the absorption sensitivity of at least one previously evaluated voxel, and defining the parallel transmission RF pulse that minimizes a weighted average of local SAR over the virtual observation points with an iterative procedure that optimizes a set of weighting factors for the weighted average to maximize the minimized weighted average of local SAR over the virtual observation points.

In accordance with yet another aspect, an MRI system includes a data storage unit to store calibration data for a model for a subject to be scanned, the model having a number of voxels, a coil array for transmitting a parallel transmission RF pulse to the subject, and a control system in communication with the data storage unit and the coil array. The control system is configured to design the parallel transmission RF pulse to control local SAR based on the model, a model compression in which the model is compressed into a plurality of virtual observation points within the model based on comparisons of peak sensitivity to SAR, and an iterative procedure applied to pulses configured to minimize a weighted average of local SAR values, the iterative procedure being configured to optimize a set of weighting factors for the plurality of virtual observation points to maximize the minimized weighted average.

### BRIEF DESCRIPTION OF THE DRAWINGS

FIG. 1 is a block diagram of one embodiment of a magnetic resonance imaging (MRI) system configured in accordance with several aspects of the disclosure.

FIG. 2 is a block diagram of an RF system and other components of the MRI system of FIG. 1 to depict a parallel transmission architecture of the RF system.

FIG. 3 is a flow diagram of one embodiment of a parallel transmission MRI method in accordance with one or more aspects of the disclosure.

FIG. 4 is a flow diagram of a parallel transmission RF pulse design method in accordance with one or more aspects of the disclosure.

FIGS. 5A and 5B are flow diagrams of an exemplary model compression method in accordance with one embodiment.

FIG. 6 is a flow diagram of an exemplary peak specific absorption rate (SAR)-constrained pulse design method in accordance with one embodiment.

FIGS. 7A-7D are graphical plots of peak local SAR as a function of root-mean-square error (RMSE) of excitation performance for various types of pulses designed via one example of the disclosed model compression and peak local SAR-constrained design methods, in comparison with the peak local SAR resulting from other pulse design methods.

FIGS. 8A-8D are graphical plots of peak local SAR and its lower bound for various types of pulses resulting from pulse design via one example of the disclosed model compression and peak local SAR-constrained design methods as a function of an overestimation factor of the disclosed methods.

### DETAILED DESCRIPTION OF THE DRAWINGS

The disclosed methods and systems are directed to designing, applying, and storing parallel transmission RF pulses for magnetic resonance imaging (MRI) scans. The disclosed methods and systems are configured for fast RF pulse design while minimizing or controlling local specific absorption rate (SAR) levels resulting from the application of parallel transmission RF pulses. With the disclosed systems and methods, local-SAR constrained, parallel transmission RF pulses can be designed, stored, and/or used on-the-fly in a time frame suitable for clinical use while remaining capable of achieving flexibly shaped excitation volumes for mitigating spatial inhomogeneities and other purposes. The RF pulses designed by the disclosed systems and methods may be specific or tailored to each subject.

Parallel transmission (pTx) systems provide increased flexibility to generate a variety of magnetization profiles in magnetic resonance imaging (MRI) relative to conventional single-channel RF systems. Parallel transmission (pTx) systems are generally limited by SAR constraints. While global or average SAR values are readily measured and easily amenable to incorporation as constraints in the pTx RF pulse design, local SAR minimization during the design of pTx RF pulses poses a challenging problem. That local SAR is generally not measurable is only part of the problem. The significant challenge is that local SAR estimation resolution in segmented tissue models constitutes an optimization problem with a heavy computational burden. An exhaustive search for the single RF pulse design that minimizes local SAR for a given patient is not feasible given the length of time that the patient would be forced to wait during a scan sequence. Calculating local SAR for every voxel for every possible pTx RF pulse may preclude the real-time, or on-the-fly, design of the pTx RF pulse.

In contrast, the disclosed systems and methods enable the RF pulses to be designed in real-time, or on-the-fly, for a specific subject, in the sense that the RF pulses can be defined in a time frame reasonable for a subject remaining in the scanner after one or more preparation or calibration scans. A reasonable time frame may, for instance, be on the order of tens of seconds or perhaps one or two minutes. In this way, the disclosed systems and methods do not introduce overly burdensome delays for the subject.

The disclosed pulse design systems and methods address the challenge presented by the varied distribution of the parallel transmission signals superimposing inside the body. As a result of the multiple (N) channels in the transmission system, many potentially important locations are to be considered for local SAR evaluation rather than just one fixed hot spot. These challenges notwithstanding, the disclosed systems and methods efficiently and effectively incorporate local SAR constraints into the pTx RF pulse design, while remaining capable of mitigating spatial flip angle inhomogeneities. The local-SAR-constrained design may decrease local SAR considerably relative to conventional pTx design with only an average SAR constraint.

The disclosed systems and methods implement a model compression technique to determine virtual observation points for the model to decrease the complexity of the prediction of the local SAR calculations. The designation of virtual observation points is based on spatial absorption sensitivity to local SAR. Rather than assign each voxel to a respective cluster of voxels, the disclosed systems and methods iteratively evaluate the spatial sensitivities of the voxels to determine whether the absorption sensitivity of a respective one of the voxels is upper bounded by a global SAR-based overestimation of the absorption sensitivity of at least one previously evaluated voxel. The resulting set of virtual observation points may then be used to reasonably predict and control the maximum local SAR, despite the small size of the set relative to the total number of voxels in the model.

The disclosed systems and methods also implement an iterative procedure to design the pulses based on the local SAR levels reached at the virtual observation points. The iterative procedure uses a set of weighting factors for the virtual observation points to represent the local SAR component to convert the design procedure into a computationally feasible condition. Pulses that minimize a weighted average of local SAR are processed by the iterative procedure to update the set of weighting factors to maximize the minimum weighted average. In some embodiments, the pulse design process may include approximating a peak local SAR as a weighted average of the local SAR. In each iterative step of the pulse design process, weighting factors may be fixed and the RF pulse is designed to minimize the weighted average of the local SAR. For a better approximation of the peak local SAR, i.e. to minimize the gap between the weighted average of the local SAR and peak local, the weighting factors are updated. The pulse design process may, in some cases, increase the weighted average of the local SAR.

The disclosed pulse design methods and systems may capture the spatial distribution of local SAR in numerical tissue models in a compressed parameterization in order to incorporate local SAR constraints within a design process having a computation time that accommodates design during an in vivo MRI scan. The design methods and systems provide a protocol-specific peak local SAR, which bounds the achievable peak local SAR for a given excitation profile fidelity. The disclosed methods and systems may reduce peak local 10 g SAR by 14-66% for slice-selective pTx excitations and 2D selective pTx excitations compared to a pTx pulse design constrained only by global SAR. While the improvement may lead to an increase in global SAR (e.g., up to 34%), the increase may be favorable in cases where local SAR constraints dominate the pulse applications.

The disclosed methods and systems are well-suited for use with a variety of different design algorithms or pulse types, including, for example, RF shimming, spoke design, spiral trajectory excitation, spatially selective excitation, uniform volume excitation, spatial-domain design for small flip angle approximation, linear class of large tip angle pulses, and optimal control methods.

The disclosed methods and systems may include or use one or more iterative procedures during the pulse design to optimize a set of weighting factors for a set of virtual observation points. Further information regarding the use of optimizers in connection with virtual observation points in pulse design is set forth in U.S. patent application Ser. No. 13/083,342 (which was filed on Apr. 8, 2011, and entitled “Parallel Transmission RF Pulse Design with Local SAR Constraints”), the entire disclosure of which is hereby incorporated by reference, and Gebhardt M, et al., “Evaluation of Maximum Local SAR for Parallel Transmission (PTx) Pulses Based on Pre-Calculated Field Data Using a Selected Subset of ‘Virtual Observation Points’,” Proc. Intl. Soc. Mag. Reson. Med., Stockholm, Sweden, p 1441 (2010). The disclosed methods and systems may include one or more features of the methods and systems described in the above-referenced documents in some embodiments.

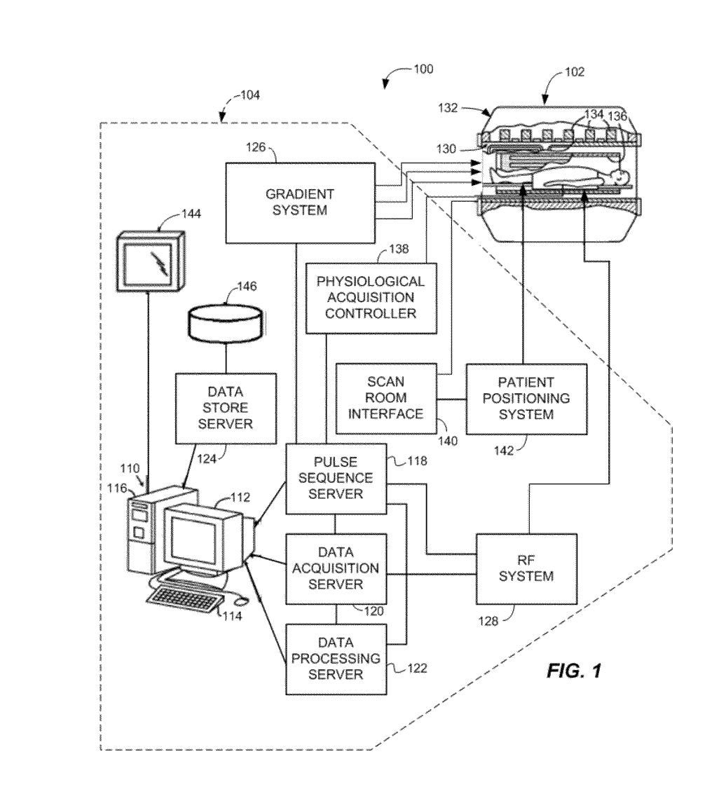

Turning now to the drawing figures, FIG. 1 depicts a magnetic resonance imaging (“MRI”) system 100 configured in accordance with several aspects of the disclosure. The MRI system 100 generally includes a scanner or data acquisition unit 102 and a control system 104 for directing the operation of the scanner 102. In an excitation phase of operation, the data acquisition unit 102 creates a magnetic resonance signal by subjecting a subject to a main magnetic field, B0, to align the individual magnetic moments, or spins, of the nuclei in the tissue with the axis of the polarizing field (conventionally, the z-axis). The main magnetic field also causes the magnetic moments to resonantly precess about the axis at their characteristic Larmor frequency. The data acquisition unit 102 then subjects the tissue to a radio frequency (RF) excitation pulse, B1, with a frequency near the Larmor frequency, so that a magnetic field in the x-y plane re-orients, flips, or tips the net aligned moment, Mz, into or toward the x-y plane, producing a net transverse magnetic moment Mxy, the so-called spin magnetization. The excitation phase is generally tailored to localize the excitation pulse to a specific region within the subject, such as a 3D slab or a relatively thin 2D slice. In a subsequent acquisition phase of operation, the data acquisition unit 102 encodes the localized region in all three dimensions for a 3D slab or only in-plane for a thin slice. The region to be imaged may be scanned by a sequence of measurement cycles in which magnetic field gradients (Gₓ, G_{y}, and G_{z}) vary according to the particular localization method being used. Tailored RF pulses may be used to localize the excitations.

The control system 104 includes a workstation 110 having one or more output interfaces (e.g., display) 112 and one or more input interfaces (e.g., keyboard) 114. The workstation 110 includes a processor 116, which may be a commercially available, programmable machine running a commercially available operating system. The workstation 110 provides an operator interface that enables scan sequences to be entered into or otherwise defined for the control system 104 and the MRI system 100. The workstation 110 may be coupled to a number of servers, including, in this example, a pulse sequence server 118, a data acquisition server 120, a data processing server 122, and a data store server 124. The workstation 110 and the servers 118, 120, 122 and 124 may communicate with each other via any desired communication technique, protocol, or standard. The servers 118, 120, 122, and 124 may correspond with respective services provided by a single workstation, such as the workstation 110. The components of the control system 104 may be coupled to one another via a data bus or network (not shown) and need not be connected via respective, dedicated communication lines as shown. Any one or more of the components of the control system 104 may be implemented as a service unit, module, or other unit implemented by a common physical machine or other device. Additional, different, or fewer components may be provided, such as combining two or more servers or providing the workstation functionality on a server or vice versa.

The pulse sequence server 118 functions in response to instructions downloaded from the workstation 110 to operate a gradient system 126 and a radio frequency (“RF”) system 128. Scan sequences containing data indicative of the RF pulses and gradients may be stored in a library or other memory of the pulse sequence server 118 or other component of the control system 104. Gradient waveforms to perform the prescribed scan are produced and applied to the gradient system 126 that excites gradient coils in a gradient coil assembly 130 to produce the magnetic field gradients Gₓ, G_{y}, and G_{z} used for position-encoding MR signals. The gradient coil assembly 130 forms part of a magnet assembly 132 that includes an annular or other polarizing magnet 134 and a whole-body RF coil array 136. In some cases, the whole-body RF coil array 136 is constructed in the form of a so-called birdcage antenna and has a number of individual antenna rods which run parallel to the patient tunnel and uniformly distributed in a circumferential arrangement around the patient tunnel. The individual antenna rods may be capacitively coupled to one another in a ring shape at one end of the birdcage antenna. A depiction of an exemplary birdcage antenna is shown in connection with the SAR calculation technique described in U.S. Patent Publication No. 2010/0327868 (“SAR Calculation for Multichannel MR Transmission Systems”), the entire disclosure of which is incorporated by reference.

RF excitation waveforms are applied to the RF coil 136 by the RF system 128 to perform a selected magnetic resonance pulse sequence. Responsive MR signals detected by the RF coil 136 or a separate local coil (not shown) are received by the RF system 128, amplified, demodulated, filtered and digitized under direction of the pulse sequence server 118. The RF system 128 includes an RF transmitter for producing a wide variety of RF pulses used in MR pulse sequences. The RF transmitter is responsive to the selected scan sequence and direction from the pulse sequence server 118 to produce RF pulses of the desired frequency, phase and pulse amplitude waveform. The generated RF pulses may be applied to the whole body RF coil 136 or to one or more local coils or coil arrays. As described below, the RF transmitter includes a plurality of transmission channels to produce RF pulses formed via the superimposition of the RF pulses generated by each transmission channel.

The RF system 128 also includes one or more RF receiver channels. Each RF receiver channel includes an RF amplifier that amplifies the MR signal received by the coil to which it is connected. Each receiver may also include a detector that collects and digitizes in-phase (I) and quadrature (Q) components of the received MR signal.

The pulse sequence server 118 may receive patient data from a physiological acquisition controller 138. The controller 138 receives signals from a number of different sensors connected to the patient, such as ECG signals from electrodes or respiratory signals from a bellows. Such signals are typically used by the pulse sequence server 118 to synchronize, or “gate”, the implementation of the scan sequence with the subject's respiration or heart beat.

The pulse sequence server 118 also connects to a scan room interface circuit 140 that receives signals from various sensors associated with the condition of the patient or subject and the magnet system. It is also through the scan room interface circuit 140 that a subject positioning system 142 receives commands to move the subject to desired positions during the scan sequence. The subject positioning system 142 may direct one or more motors (not shown) that drive a bed and, thus, the subject, to a desired position.

The digitized MR signal samples produced by the RF system 128 are received by the data acquisition server 120. The data acquisition server 120 operates in response to instructions downloaded from the workstation 110 to receive the real-time MR data and provide buffer storage such that no data is lost by data overrun. In some scan sequences, the data acquisition server 120 does little more than pass the acquired MR data to the data processor server 122. However, in scans that require information derived from acquired MR data to control the further performance of the scan, the data acquisition server 120 is programmed to produce such information and convey it to the pulse sequence server 118. For example, during calibration or other pre-scans, MR data is acquired and used to calibrate the pulse sequence performed by the pulse sequence server 118. The calibration data may be stored in a memory or storage device or other unit of, associated with, or in communication with, any of the aforementioned servers or other devices. Also, navigator signals may be acquired during a scan and used to adjust RF or gradient system operating parameters or to control the view order in which k-space is sampled. The data acquisition server 120 may be employed to process MR signals used to detect the arrival of contrast agent in a magnetic resonance angiography (MRA) scan. In all these examples, the data acquisition server 120 acquires MR data and processes it in real-time to produce information that is used to control the scan.

The data processing server 122 receives MR data from the data acquisition server 120 and processes it in accordance with instructions downloaded from the workstation 110. Such processing may include, for example, Fourier transformation of raw k-space MR data to produce two or three-dimensional images, the application of filters to a reconstructed image, the performance of back-projection image reconstruction of acquired MR data, the calculation of functional MR images, the calculation of motion or flow images, segmentation, rendering, or other visualization processes.

Images reconstructed by the data processing server 122 are conveyed back to the workstation 110 for storage and/or display. Real-time images may be stored in a database memory cache (not shown) from which they may be output to the display 112 or an auxiliary terminal or console 144, which may be located near the magnet assembly 132 for use by attending physicians or other operators. Batch mode images or selected real time images are stored in a database on mass storage device 146, which may include any desired storage medium. When such images have been reconstructed and transferred to storage, the data processing server 122 notifies the data store server 124 on the workstation 110. The workstation 110 may be used by an operator to archive the images, produce films, or send the images via a network to other facilities.

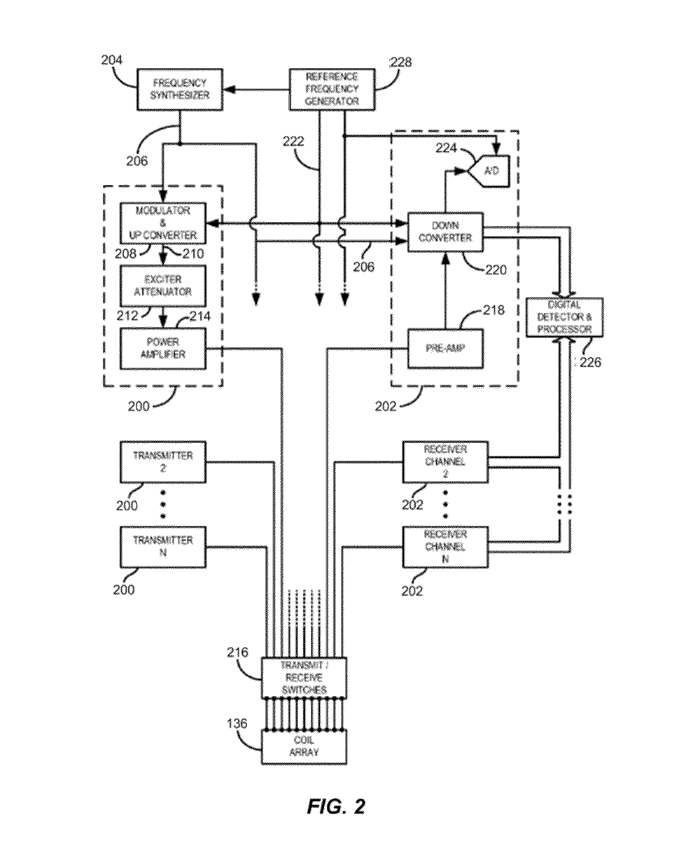

Referring now to FIG. 2, the RF system 128 and other components of the system 100 are shown in greater detail. The whole body coil array 136 generally includes a plurality of coil elements that can be separately driven by a plurality of RF transmitters 200 to produce a desired RF field-of-excitation (“FOX”). Each RF transmitter 200 forms one of the array of channels that, when superimposed, collectively define the composite RF signal. The coil array 136 may also be used with a plurality of receive channels 202. Alternatively or additionally, another whole body RF coil array (not shown) or another local RF coil may be used to acquire the MR signals. A variety of different coil array structures may be used as part of the system 100 (FIG. 1).

The RF system 126 includes a set of transmitters 200, each of which produces an individual, selected RF excitation field. The base, or carrier, frequency of this RF excitation field is produced under control of a frequency synthesizer 204, which receives a set of digital control signals from the pulse sequence server 118. These control signals may include data representative of the frequency and phase of the RF carrier signal, which may be produced at an output 206. The RF carrier is applied to a modulator and up converter 208 in each transmitter 200, where its amplitude is modulated in response to a signal also received from the pulse sequence server 118. The signal defines the envelope of the RF excitation pulse to be produced and is generated by sequentially reading out a series of stored digital values. These stored digital values may be changed to enable any desired RF pulse envelope to be produced by each transmitter 200.

The magnitude of the RF excitation pulse produced at an output 210 is attenuated by an exciter attenuator circuit 212 in each transmitter 200. Each attenuator circuit 212 receives a digital command from the pulse sequence server 118. The attenuated RF excitation pulses are applied to a power amplifier 214 in each transmitter 200. The power amplifiers 214 are current source devices that connect to respective transmit inputs on a set of transmit/receive switches 216. In this example, a desired number N of the transmitters 200 are employed and connected through a corresponding number N of the transmit/receive switches 216 to a corresponding number N of the coil elements in the RF coil array 136. Other transmitter arrangements may be used.

The signal produced by the subject is picked up by the coil array 200 and applied to the inputs of the set of receive channels 202. A pre-amplifier 218 in each receiver channel 202 amplifies the signal by an amount determined by a digital attenuation signal received from the pulse sequence server 118 (FIG. 1). The received signal is at or around the Larmor frequency, and this high frequency signal is down converted in a two-step process by a down converter 220, which first mixes the NMR signal with the carrier signal on the line 206, and then mixes the resulting difference signal with a reference signal on a line 222. The down converter NMR signal is applied to the input of an analog-to-digital (“A/D”) converter 224 which samples and digitizes the analog signal and applies it to a digital detector and signal processor 226. The digital detector and signal processor 226 produces 16-bit in-phase (I) values and 16-bit quadrature (Q) values corresponding to the received signal, but other formats may be used. The resulting stream of digitized I and Q values of the received signal are output to the data acquisition server 120 (FIG. 1). The reference signal as well as the sampling signal applied to the A/D converter 224 are produced by a reference frequency generator 228.

The transmit/receive switches 216 are controlled and directed by the pulse sequence server 118 (FIG. 1) to connect the N transmitters 200 to the N coil elements in the coil array 136 during those parts of the pulse sequence in which an RF field is to be produced. Each transmitter 200 is separately controlled by the pulse sequence server 118 (FIG. 1) to produce an RF field of a desired amplitude, frequency, phase, and envelope at each of the N coil elements. The combined RF fields of the N coil elements produce the prescribed B₁ field throughout the region of interest in the subject during the imaging phase of the procedure.

When the B₁ field is not produced, the pulse sequence server 118 directs the transmit/receive switches 216 to connect each of the N receive channels to the respective N coil elements. Signals produced by the excited spins in the subject are picked up and separately processed as described above.

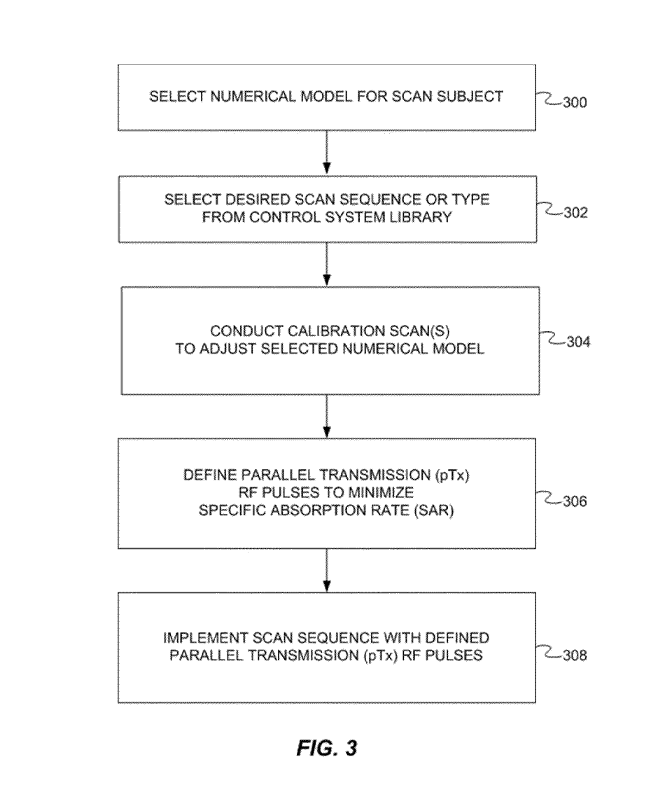

FIG. 3 depicts one example of a pTx RF pulse design method in accordance several aspects of the disclosure. In the interest of tailoring the pulse design to a specific subject, the method may begin with act 300 in which a numerical model is selected as a proxy for a scan subject. The numerical model may correspond with any model in the library of body models relied upon by MRI systems for a voxelized representation of the complex conductivity distribution presented by the human body. For example, the models available for selection may be those in the so-called “virtual family,” which includes an average adult male model (Duke), an average adult female model (Ella), and other models for children, obese subjects, or other representations of a type of patient. Other commercially available models are also suitable for use with the disclosed methods, including, for instance, the HUGO model. The disclosed methods are well suited for use with any numerical body model, model type, or model source. The selected model also need not be based on a pre-existing numerical model, but instead be generated via a set of comprehensive scans of the subject. The numerical model may be selected by an operator via an input interface provided by the workstation 110 (FIG. 1), which may, in turn, access data indicative of the numerical model stored in, for example, the mass storage unit 146 (FIG. 1). The manner in which one of the models is selected for use in connection with a particular subject may vary considerably, such as being automated.

In this example, the method includes an act 302 in which a preliminary scan sequence is selected from a library of predetermined scan sequences made available by the control system 104 (FIG. 1). The library may include discrete scan sequences configured for respective clinical or diagnostic purposes. The scan sequence may be preliminary in the sense that it provides a general framework of the RF pulses to support the desired clinical or diagnostic purpose. The scan sequence may or may not include the details of each RF pulse. Alternatively, an operator may be provided with an option to customize the RF pulses of the scan sequence. In either case, the pTX RF pulse design methods described herein are then used to customize the scan sequence to minimize local SAR for the specific subject. The scan sequence selection may also be made by an operator using the workstation 110 (FIG. 1). The scan sequence library may also be stored on the mass storage unit 146 (FIG. 1) or any other storage medium of (or in communication with) one or more of the components of the control system 104 (FIG. 1). The scan sequence selection may alternatively be made at a different point in the process, in which case the act 302 may instead be directed to selecting some other context for the pulse design, including, for instance, the general type of scan (e.g., whole body or head), a body part to be scanned (e.g. arm), or a clinical purpose.

A calibration act 304 may be implemented after selection of the numerical model and the scan sequence (or scan type). The calibration act 304 is generally directed to adjusting the selected numerical model before the model is used for electric field calculations that support the RF pulse design. Generally speaking, each calibration scan provides feedback regarding the electric and magnetic fields produced in a tissue segment by the respective array elements of the system for a given pTx pulse. The calibration act 304 may include any number of scans, as desired, and may involve standard calibration techniques used with commercially available scanners used in typical clinical contexts. The calibration act 304 may be implemented before the selection of the scan sequence.

The calibration scan(s) are used to adjust the numerical model of the body based on the transverse magnetization resulting from the RF pulses applied during the calibration scan(s). Each calibration scan may involve any desired combination of the parallel transmit channels 200. The magnetization resulting from each scan is captured and processed by the RF system 128, the data acquisition server 120, and other components of the control system 104 in much the same manner as an RF pulse designed for clinical purposes. However, the data is instead used to improve the model's ability to predict the magnetic field generated in the subject's body resulting from a given RF pulse by incorporating or adjusting tissue properties, such as conductivity, dielectricity, density, etc. In this way, the model may be adjusted to reflect anatomical or other differences of the specific subject relative to the numerical model that should be taken into account during RF pulse design. Calibration data, which may be indicative of, for instance, the calibration scan results or the adjustments to the model, may be stored in any server, device, component, or other unit of the control system 104 (FIG. 1).

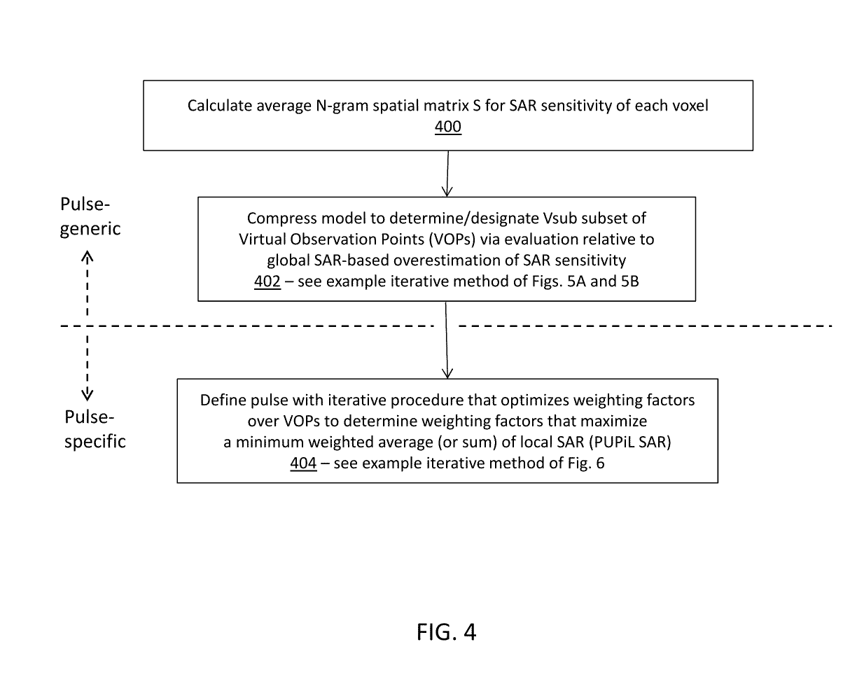

After completion of the calibration scans, and once the numerical model has been adjusted for the specific subject and scan sequence, an RF pulse design act 306 is implemented to define and select an RF pulse with one or more local SAR-based constraints. The RF pulse design act 306 may be performed on, for instance, the workstation 110 (FIG. 1), or any one or more components of the control system 104 (FIG. 1) in communication therewith. Further details regarding the procedure implemented by the workstation 110 in the act 306, such as the design constraint(s), are set forth below in connection with FIGS. 4-6. The RF pulse design process uses one or more iterative procedures to define a pulse that minimizes a weighted average of local SAR by optimizing a set of weights to maximize the minimized weighted average.

Once the RF pulse is defined and selected, an operator may use the workstation 110 (FIG. 1) or other operator interface to conduct a scan sequence in act 308 that implements the pTx RF pulses defined in the act 306. Any number of pTx RF pulses may be defined and, thus, implemented during the scan. In some cases, one or more of the acts shown in FIG. 3 are repeated to support the definition of separate pTx RF pulses incorporated into a single scan sequence conducted in the act 308.

Further details regarding the pTx RF pulse design method are provided in connection with an example shown in FIG. 4. The exemplary method may begin in act 400 with the pre-calculation of a representation of the electric field (or electric field absorption sensitivity) for each voxel, v, in the numerical model resulting from a unit RF signal input of 1 Volt of 10 us duration or other voltage and/or duration. These electric (and magnetic) field calculations may be implemented using a known technique, such as the Finite Difference Time Domain (FDTD) method. Generally speaking, the FDTD method provides a numerical simulation of the electric and magnetic fields. These simulations of the fields in a segmented tissue ultimately support the estimates of the local SAR (and, in some cases, global SAR) due to the RF pulses transmitted by the pTx coil array 136 (FIG. 2). In this case, the unit signal is applied via each individual coil in the array 136 to generate a spatial matrix S representative of the electric field absorbed by the voxel due to each unit RF signal. More specifically, for any RF, b, the electrical field at a voxel, v, can be calculated as Eᵥ=Qᵥb, where the k^{th} column of Qᵥ is the pre-calculated electrical field vector due to a unit signal of channel k in voxel v. With the density, ρ, and the electric conductivity, σ, of, for instance, the brain model, local SAR at a voxel v can be determined by

$${SAR}_{v} = {\sum }_{t} {SAR}_{v} ( t ) = {\sum }_{t} \frac{{σ}_{v}}{2 {ρ}_{v}} {‖ {E}_{v} ( t ) ‖}^{2} = {\sum }_{t} {b ( t )}^{′} {S}_{v} b ( t ) , \\ where$$

$${S}_{v} = \frac{{σ}_{v}}{2 {ρ}_{v}} {Q}_{v}^{′} {Q}_{v} .$$

In view of the foregoing relationship, the spatial matrix, S, is indicative of the sensitivity of a particular voxel to electric field absorption. The spatial matrix, S, does not incorporate the details of the RF excitation or any other temporal information. Instead, the spatial matrix, S, reflects the anatomy of the subject, the positioning of the RF coil(s), and other non-temporal, spatial parameters.

In this example, the pre-calculation of the fields and, thus, the spatial matrices Sᵥ for local SAR sensitivity representation, are generated and averaged for a volume of the numerical model surrounding each voxel v, i.e., an N-gram volume such as a 10 g volume. For N-gram SAR calculation, the fields in the N-gram region around the voxel v are pre-calculated using the FDTD technique, and the local SAR in the region may be averaged as follows:

$${SAR}_{v , ngram} = \frac{{\sum }_{w ∈ {Ngram}_{v}} {SAR}_{w}}{\vert {Ngram}_{v} \vert} = {\sum }_{t} {b ( t )}^{′} ( \frac{{\sum }_{w ∈ {Ngram}_{v}} {S}_{w}}{\vert {Ngram}_{v} \vert} ) b ( t ) = {\sum }_{t} {b ( t )}^{′} {S}_{v , Ngram} b ( t )$$

Further details regarding exemplary procedures for the pre-calculation of the spatial matrix S as an indication of SAR sensitivity are set forth in U.S. Patent Publication No. 2010/0308825 (“Method and Device for Selecting Body Model Positions for SAR Monitoring of a Magnetic Resonance Transmit Array”), and U.S. application Ser. No. 13/045,832 (“Method for Determining Sensitivity Matrices for Hotspots”), the entire disclosures of which are hereby incorporated by reference.

Upon completion of the pre-calculation of the spatial matrix for the absorption sensitivity of each voxel, the selected (and calibrated) model is compressed in act 402 into a set of virtual observation points (VOPs). The model compression is based on comparisons of peak sensitivity to local specific absorption rate (SAR). The set of VOPs is determined or designated by evaluating the absorption sensitivity of each voxel relative to a global SAR-based overestimation of SAR spatial sensitivity. The global SAR-based overestimation may define or establish an upper bound matrix for finding the virtual observation points via an iterative process. The overestimation may be calculated as a sum of the spatial matrix of the virtual observation point and a global SAR matrix scaled by an overestimation factor. The model may then be compressed by iteratively evaluating the voxels to determine whether the absorption sensitivity of a respective one of the voxels is upper bounded by the absorption sensitivity of at least one previously evaluated voxel. If the absorption sensitivity is not upper bounded, then the voxel is added to the set of VOPs. As described below, the upper bound may be established via an overestimation factor, which, in some embodiments, may be used to scale a global SAR term. For example, an upper and lower bound for the VOP determination may be as follows:

$${max}_{v ∈ {V}_{sub}} \{ {\sum }_{t} {b ( t )}^{′} {S}_{v , 10 g} b ( t ) \} \leq {max}_{v ∈ {V}_{all}} \{ {\sum }_{t} {b ( t )}^{′} {S}_{v , 10 g} b ( t ) \} \leq {max}_{v ∈ {V}_{sub}} \{ {\sum }_{t} {b ( t )}^{′} {S}_{v , 10 g} b ( t ) \} + {ɛ}_{G} {\sum }_{t} {b ( t )}^{′} {S}_{Global} b ( t ) .$$

The VOPs are the subset, V_{sub}, of the voxels that satisfy the above expression for any pulse, b(t). Because V_{sub} is a subset of all of the voxels, the lower bound is satisfied. The upper bound determination may be implemented via an iterative procedure that allows each voxel in the model to be jointly upper bounded by all of the VOPs within the overestimating term. For any voxel v, there exists a set of voxel-dependent nonnegative coefficients c_{w,v} whose sum is unity over the VOPs, such that

$${\sum }_{t} b {( t )}^{′} {S}_{v , 10 g} b ( t ) \leq {\sum }_{w ∈ {V}_{sub}} {c}_{w , v} ( {\sum }_{t} {b ( t )}^{′} {S}_{w , 10 g} b ( t ) ) + {ɛ}_{G} {\sum }_{t} {b ( t )}^{′} {S}_{Global} b ( t )$$

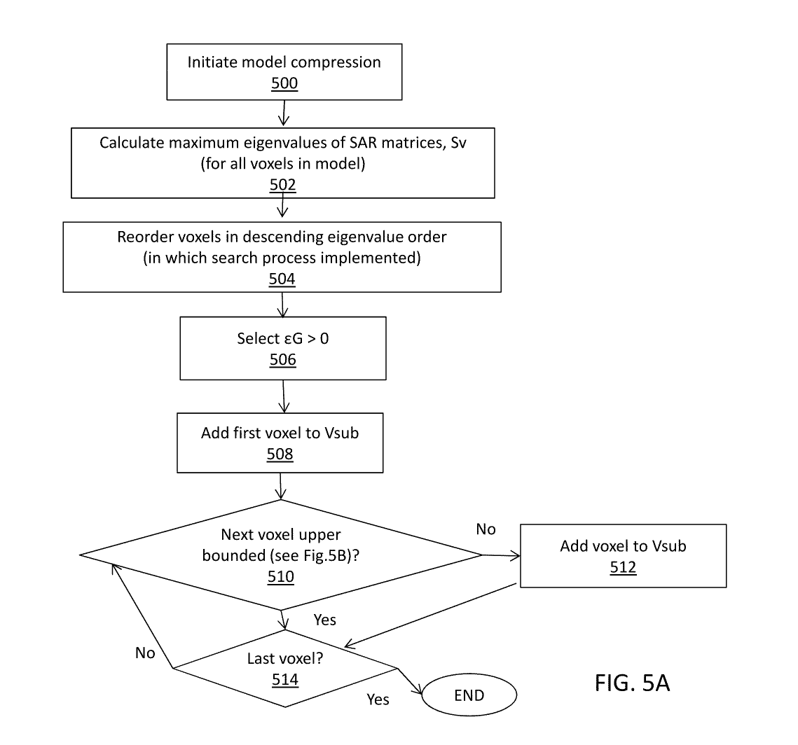

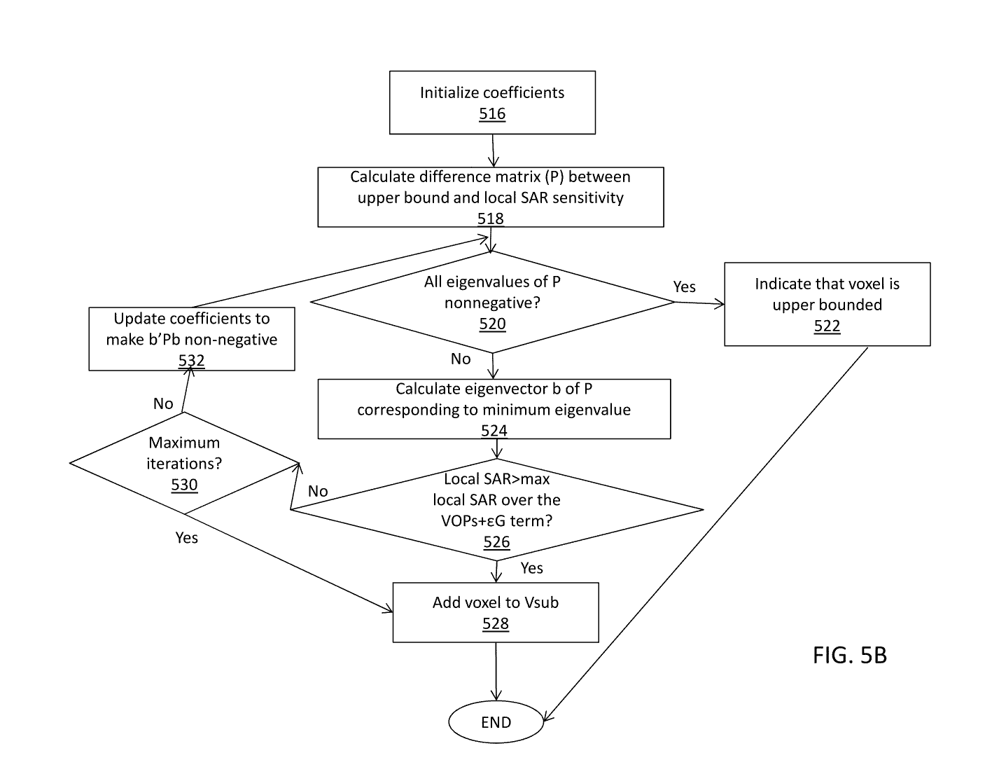

As a result, several VOPs may contribute to bound a particular voxel. Which particular VOP ultimately upper bounds the voxel is allowed to depend on the pulse waveform b(t). Thus, the compression method captures more dependencies among the voxels in the model than in an compression method in which each voxel is only represented by a single VOP. The compression method may thus decrease the number of voxels in V_{sub} required to estimate local SAR. Further details regarding the model compression method are set forth below in connection with the examples of FIGS. 5A and 5B, which provide a technique to replace the above VOP condition with the following matrix inequality:

$${S}_{v , 10 g} \leq {\sum }_{w ∈ {V}_{sub}} {c}_{w , v} {S}_{w , 10 g} + {ɛ}_{G} {S}_{Global} ,$$

which is true if all the eigenvalues of the matrix,

$${\sum }_{w ∈ {V}_{sub}} {c}_{w , v} {S}_{w , 10 g} + {ɛ}_{G} {S}_{Global} - {S}_{v , 10 g} ,$$

are nonnegative.

The overestimation factor ∈ may be considered a tuning factor of the compression procedure and pTx pulse design methods disclosed herein. By decreasing the overestimation factor ∈, the approximation of the maximum local SAR within the model is tighter, and the number of virtual observation points is increased. Conversely, by increasing the overestimation factor E, the approximation of the maximum local SAR within the model is less tight, and the number of virtual observation points is decreased.

Other model compression techniques involving a spatial matrix indicative of absorption sensitivity may be used to determine or designate the VOPs. While some embodiments of the model compression method may use a greedy algorithm, other techniques may be used to determine an optimal or near optimal solution.

Upon completion of the model compression act 402, the spatial sensitivity of the model and coil design to local SAR peaks or hotspots is captured via the virtual observation points (VOPs). Up through this point in the method, the processing is not limited to any particular type of pulse or pulse design. The processing is pulse-generic, as the set of VOPs may be used to design a variety of different parallel transmission pulses. The VOPs may thus be pre-computed once for a given model and array configuration, and then later applied in subsequent computations directed to efficiently estimating peak local SAR due to a given pTx RF pulse. By capturing peaks in the local SAR distribution with VOPs, it becomes feasible to incorporate peak local SAR constraints in pTx RF designs.

An iterative procedure to design a specific parallel transmission pulse with peak local SAR constraints based on the set of VOPs is implemented in act 404. The iterative procedure is configured to design the pulse by optimizing a set of weighting factors for the VOPs. The pulse is configured to minimize a weighted average of local SAR. The iterative procedure is configured to determine values for the weighting factors that maximize a minimum weighted average of local SAR. Use of the weighting factors allows one or more pulse design constraints to be solved or otherwise incorporated into the pulse design through the use of commercially available optimizers.

The pTx pulse design methods disclosed herein may be based on one or more local SAR-based constraints. Instead of minimizing the maximum local SAR of the entire model, the lower bound in the above-described VOP condition is minimized, which is a tight lower bound for the small overestimating factor, ∈_{G}, and which may also equal the maximum local SAR of the entire model if the voxel of the maximum local SAR belongs to one of the VOPs. The performance of this pTx pulse design may be evaluated for pulses with a fixed excitation performance target, which may be the root mean square error (RMSE) relative to the desired transverse magnetization profile, m_{d}, inside the region of interest (ROI). The transverse magnetization, m(b), by transmitting pTx RF pulse b(t), may be calculated using Bloch equation simulations. The disclosed methods and systems may be applied for excitation targets defined in terms of either least-squares or magnitude-least-squares.

The iterative procedure may be configured to determine a lower bound, SAR_{low}, of the peak local SAR in the subset V_{sub} that can be achieved with the fixed RMSE. The pTx RF pulse, b(t), to reach the lower bound may then be determined as follows:

$${SAR}_{low} \leq {min}_{RMSE = c} ( {max}_{v ∈ {V}_{sub}} \{ {\sum }_{t} {b ( t )}^{′} {S}_{v , 10 g} b ( t ) \} ) .$$

Notwithstanding the advantages of the model compression technique described above, minimizing the design criterion may be difficult within the time constraints of the MRI scan. To decrease the computational time involved, an approximation involving a set of weighting factors is employed. The approximation determination is generally implemented in the act 404 once the set of VOPs are determined.

The act 404 may consider pTx RF pulses that minimize the weighted average of the local SAR. Among the pTx RF pulses designed, the lower bound of the peak local SAR over VOPs and a pTx RF pulse that minimizes the peak local SAR over VOPs are determined. Given nonnegative weighting factors, wᵥ, whose sum is equal to one, let b_{w}(t) be a pTx RF pulse, with a fixed RMSE performance, c, that minimizes the weighted average of the local SAR:

$${b}_{w} ( t ) ≡ {arg min}_{b ( t )} \{ {\sum }_{t} {b ( t )}^{′} ( {\sum }_{v ∈ {V}_{sub}} {w}_{v} {S}_{v , 10 g} ) b ( t ) \}$$

where wᵥ are non-negative weighting factors whose sum is equal to one. Each weighting factor is applied to a respective one of the VOP spatial matrices.

The approximation effectively converts the local SAR-based design constraint into a problem for which a solution is computationally feasible using one of several available or known optimizers, such as those utilizing a conjugate gradient method or other codes. Please see, for example, Setsompop, K., et al., “Magnitude least squares optimization for parallel radio frequency excitation design demonstrated at 7 Tesla with eight channel,” Magn Reson Med, Vol. 59(4), p. 908-15 (2008), Setsompop, K., et al., “Parallel RF transmission with eight channels at 3 Tesla,” Magn Reson Med, Vol. 56(5), p. 1163-71 (2006), Grissom, W., et al., “Spatial domain method for the design of RF pulses in multicoil parallel excitation,” Magn Reson Med, Vol. 56(3), p. 620-9 (2006), and Gumbrecht R., et al., “Fast high-flip pTx pulse design to mitigate B1+ inhomogeneity using composite pulses at 7 T,” 18th Annual Meeting of ISMRM (2010). Using these pulse design methods to resolve the approximation constraint, the approximation is updated via the iterative process to effectively implement the design constraint.

The iterative procedure may be used to find the ultimate peak local SAR (PUPiL SAR), which may correspond with the maximum, among all the weighting factors, of the minimum weighted average of the local SAR, given the VOPs and a fixed mitigation error as follows:

$$PUPiL SAR ≡ {max}_{{w}_{v}} \{ {SAR}_{w} \} = {max}_{{w}_{v}} \{ {\sum }_{t} {{b}_{w} ( t )}^{′} ( {\sum }_{v ∈ {V}_{sub}} {w}_{v} {S}_{v , 10 g} ) {b}_{w} ( t ) \}$$

such that

$${\sum }_{v ∈ {V}_{sub}} {w}_{v} = 1$$

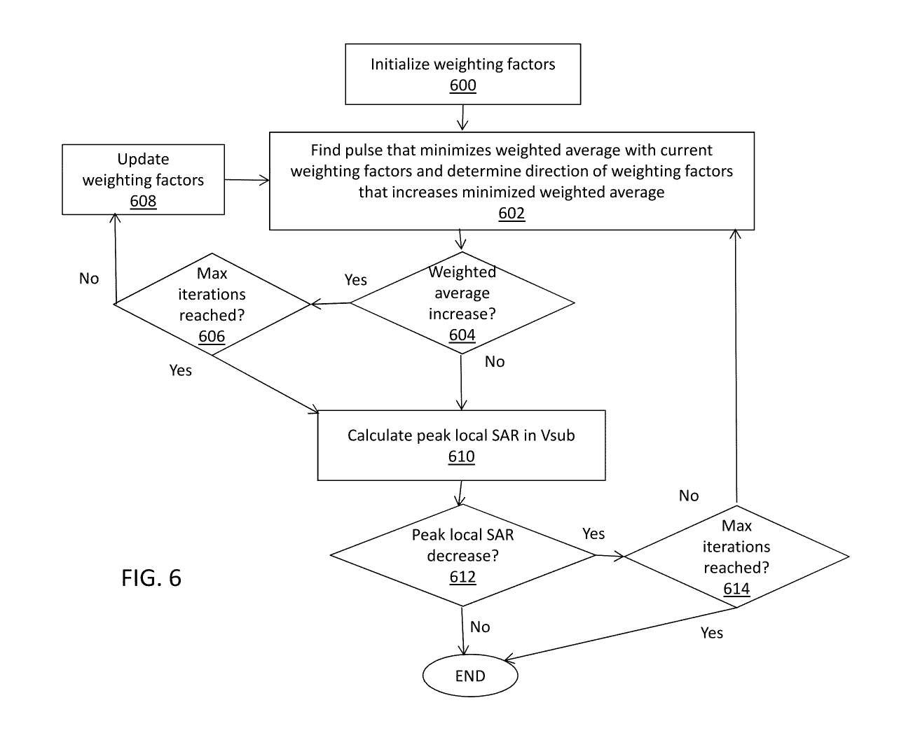

and wᵥ≧0. Further details of the iterative procedure are set forth in connection with the example of FIG. 6.

Turning now to FIG. 5, one example of a model compression method is initiated in act 500, during which iteration coefficients may be initialized as described below. The model compression procedure iteratively evaluates the voxels in the model to determine whether the absorption sensitivity of a respective one of the voxels is upper-bounded by the absorption sensitivity of at least one previously evaluated voxel. The upper bound is defined as the matrix sum of the spatial absorption sensitivity matrix of a virtual observation point and a global SAR matrix scaled by the overestimation factor, as described above.

At the outset, in act 502, the maximum eigenvalues of the absorption sensitivity matrices, S_{v,10g}, are calculated for all the voxels in the model. The voxels may then be reordered in act 504 based on the maximum eigenvalues in a descending order. Selection of the overestimation factor ∈ may then occur in act 506 to tune the complexity or extent of the compression, thereby to trading off the number of voxels in the VOP subset (V_{sub}) and the tightness of the bound. The selection may alternatively occur at any time before the above-described calculation and ordering acts.

The iterative procedure begins in act 508 with the addition of the first voxel in the model to the VOP subset V_{sub}. Each successive voxel is then checked in a decision block 510 that determines whether the absorption sensitivity of the voxel is upper-bounded by previously determined VOPs in V_{sub}. If not upper-bounded, then the voxel is designated as another VOP in act 512 and added to V_{sub}. If the voxel is upper-bounded, then control passes to another decision block 514 that determines whether all of the voxels in the model have been considered. If not, control returns to the decision block 510 for evaluation of the next voxel. Otherwise, the model compression procedure is complete.

FIG. 5B shows one exemplary procedure for determining whether the k^{th} voxel, v, can be upper-bounded or not by previously determined the VOPs. Ideally, all possible choices of the coefficient, c_{w,v} are evaluated. To reduce the computation time, an iterative method that searches over the coefficients, c_{w,v}, as follows. In act 516, the coefficients are initialized if not already done so. A difference matrix, P, is calculated in act 518 to determine the difference between the upper bound and the local SAR sensitivity of the current voxel as follows:

$$P = {\sum }_{w ∈ {V}_{sub}} {c}_{w , v} {S}_{w , 10 g} + {ɛ}_{G} {S}_{Global} - {S}_{v , 10 g}$$

A decision block 520 determines whether all the eigenvalues of the difference matrix are nonnegative, in which case the voxel is upper-bounded by previously determined VOPs. An indication to that effect may be stored in act 522. Otherwise, control passes to act 524, where the eigenvector, b, of P corresponding to the minimum eigenvalue is calculated. A decision block 526 then determines whether, by vector b, the local SAR at the voxel v is greater than the maximum local SAR over the VOPs plus the overestimating term, i.e.

$${b}^{′} {S}_{v , 10 g} b > {max}_{w ∈ {V}_{sub}} \{ {b}^{′} {S}_{w , 10 g} b \} + {ɛ}_{G} {b}^{′} {S}_{Global} b ,$$

the voxel v cannot be upper-bounded, and the voxel is designated as a VOP in act 528. If not, then control passes to another decision block 530 in which the number of iterations is checked against a maximum. If not, then the coefficients, c_{w,v}, are updated to make b′Pb nonnegative in act 532, and control returns to the decision block 520. If the number of iterations exceeds a pre-selected maximum number of iterations, the voxel is designated a VOP and added to V_{sub} as shown.

After performing the iterative procedures of FIGS. 5A and 5B, the subset, V_{sub}, may be used to control peak local SAR in the pulse design. The overestimating factor, ∈_{G}, trades off the complexity of the design and the tightness of the upper-bound of the maximum local SAR estimation. By decreasing the overestimating factor, the approximation of the maximum local SAR is more accurate but the number of voxels in V_{sub} used to achieve this improved accuracy of bounds on maximum and minimum local SAR is increased.

FIG. 6 depicts one example of a pulse design method based on the VOPs of the model. The method includes an iterative weighted approximation procedure initiated in a block 600, in which the set of weighting factors wᵥ are initialized. In one example, the weighting factors begin at the same value such that the each wᵥ=1/(the number of VOPs). In this embodiment, the iterative procedure includes an outer iterative procedure configured to minimize a peak local SAR value for the parallel transmission RF pulse being defined. An inner iterative procedure is nested within the outer iterative procedure to ensure that the weighting factors for the pulse being designed maximizes a minimized weighted average of the local SAR levels or values over the VOPs (i.e., in V_{sub}).

The outer iterative procedure begins in act 602, in which a pulse is found that minimizes the weighted average with the current weighting factors. For example, the RF pulses may be designed with the second order regularization term b′Sb. The act 602 may also include an analysis of the contributions of each VOP to the weighted average to determine a direction to change each weighting factor that increases the minimized weighted average after each iteration of the iterative procedure. For example, the weighting factor of a VOP that has a large contribution may be increased to such an extent that, in an ideal case, its weighting factor approaches 1 (and all other weighting factors thus approach 0).

A decision block 604 may then determine whether the weighted average of the local SAR levels over the VOPs increased. If yes, then control passes to another decision block 606 that checks to see whether a maximum number of iterations has been reached for the inner iterative procedure. If not, then the weighting factors are updated in act 608 in accordance with the directions resulting from the analysis in act 602, and another pulse is designed in act 602. If the weighted average does not increase, then control passes to act 610 to calculate the peak local SAR over the VOPs. If the peak local SAR decreased, then control passes to another decision block 614 to determine whether a maximum number of iterations has been reached for the outer iterative procedure. If not, then control returns to the act 602 for further pulse design via optimization of the weighting factors. Alternatively, control may return to the act 608 (or a similar block) to update the weighting factors, which may be useful to avoid a local minima and/or maxima. Once the peak local SAR does not increase, then the pulse design procedure is complete.

The weighting factors may thus be updated through a gradient descent method. In some embodiments of the pulse design procedure, each iteration includes (1) calculating the local SAR in V_{sub} deposited by b_{w}(t), (2) predicting the direction of the weighting factors, wᵥ, that increases the weighted average of the local SAR, and (3) updating the weighting factors, wᵥ, to the direction with only a small change in each iterative step. The iterative process is stopped if the weighted average of the local SAR, SAR_{w}, does not increase or until it reaches the preselected number of iterations.

The above-described iterative procedure may be used in some embodiments to estimate the global maxima, PUPiL SAR, by searching over many weighting factors. After determining a lower bound, the procedure may design pTx RF pulses whose peak local SAR over the VOPs approaches the lower bound. In determining PUPiL SAR, the maximum lower bound is found. However, the above-described procedure minimizes the peak local SAR over the VOPs. While, in some cases, only the RF pulses, b_{w}(t), that minimize the weighted average of the local SAR are considered, the RF pulse that has the minimum peak local SAR over the VOPs is determined as follows:

$$b ( t ) = {arg min}_{{b}_{w} ( t )} ( {max}_{v ∈ {V}_{sub}} \{ {\sum }_{t} {{b}_{w} ( t )}^{′} {S}_{v , 10 g} {b}_{w} ( t ) \} ) ,$$

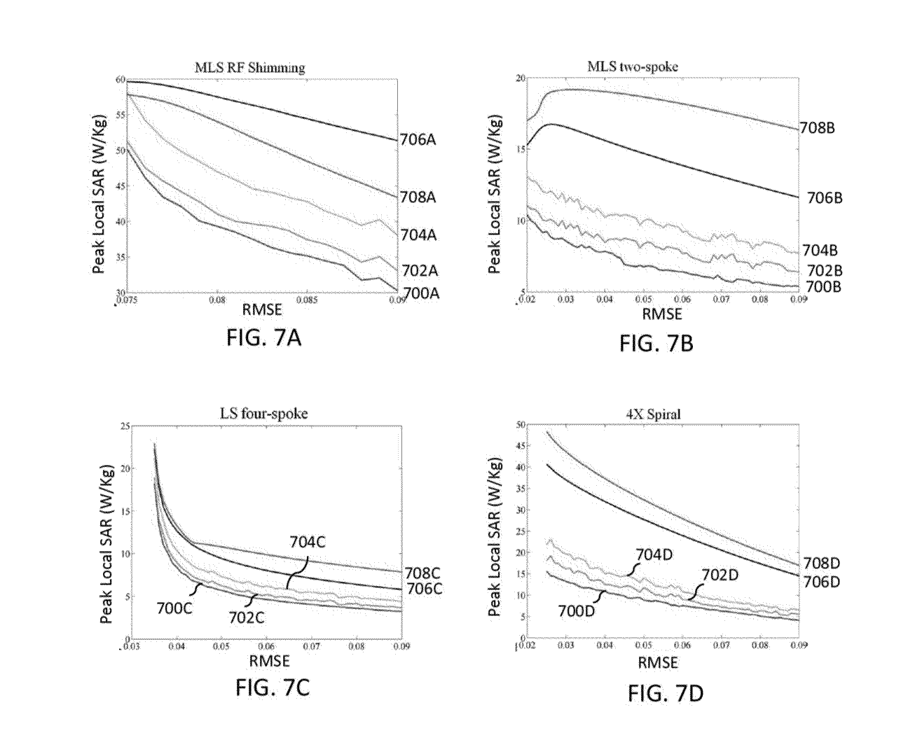

FIGS. 7A-7D show an exemplary application of the above-described local SAR-constrained pulse design methods for two different low-flip-angle applications. In these examples, the pulse design may be achieved in sub-minute calculation times, which is still feasible for in vivo applications. The first application is directed to mitigating B1+ magnitude inhomogeneity in the Ella head model at 7 T for an axial, 1-cm thick, slice-selective excitation at the S-I center of the RF coil array. The second application uses a spiral-based excitation k-space trajectory with a square-box target pattern of uniform intensity in dimensions of x×y=63×63 mm², with zero excitation outside the box. The desired profiles are chosen to have the maximum normalized transverse magnetization of 0.5 (equivalent to a 30 degree flip angle) assuming that the fully relaxed longitudinal magnetization is unity. For the slice-selective application, three different design categories for pTx pulses are considered, namely RF shimming with an MLS criterion, a two-spoke pulse with the MLS criterion, and a four-spoke pulse with the LS criterion. For the box excitation, a 2D spiral pTx pulse with the MLS criterion is used with an acceleration factor of four and FOV of 27 cm in x and y, and resolution of 3 mm. In this example, the simulated B1+ fields were used and B0 was assumed to be homogenous. For these simulations, the duty cycle was assumed to be 100%, i.e. TR equals the duration of the RF pulse. The durations of RF pulses are 1.6 ms for MLS RF Shimming, 2.51 ms for MLS two spokes, 4.16 ms for LS four spokes, and 5.95 ms for 2D spiral pTx pulse. An overestimation level of ∈_{G}=1 was used.

In FIGS. 7A-7D, the peak local SAR over the entire model is shown as follows. A lower bound (the estimate of the PUPiL SAR) 700A-D and a local SAR constrained design 702A-D generated by the disclosed methods are shown with, for comparison purposes, an upper bound (the overestimation of the peak local SAR determined by VOPs) 704A-D, a global SAR constrained design 706A-D, and an RF power constrained design 708A-D. For all the cases, the peak local SAR of the proposed method 702 is larger than the lower bound 700 and is less than the upper bound 704. The reduction of the peak local SAR varies with the pulse design method. The ratio of the peak local SAR of proposed local SAR constrained design to the peak local SAR of global SAR constrained design was 64-86% for MLS RF Shimming, 53-72% for MLS two spokes, 60-85% for LS four spokes, and 34-48% for MLS 2D spiral. The ratio of the peak local SAR of proposed local SAR constrained design to the lower bound was 102-109% for MLS RF Shimming, 106-135% for MLS two spokes, 104-119% for LS four spokes, and 112-136% for MLS 2D spiral. The ratio of the peak local SAR of proposed local SAR constrained design to the upper bound was 87-90% for MLS RF Shimming, 83-86% for MLS two spokes, 83-89% for LS four spokes, and 81-85% for MLS 2D spiral.

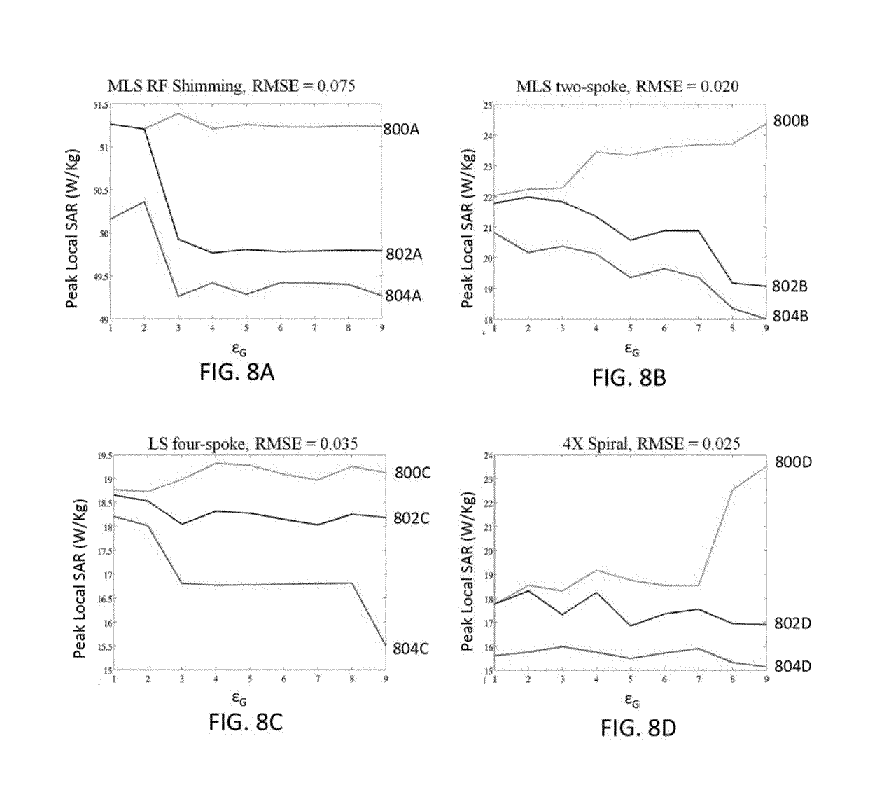

FIGS. 8A-8D plot the peak local SAR over the entire model 800A-D, the peak local SAR of the voxels in the subset V_{sub} determined by the model compression method 802A-D, and a lower bound (the estimate of the PUPiL SAR) 804A-D, are shown for a range of overestimation values ∈_{G}=1-9 and four pTx RF designs. By using the smaller overestimating factors, the difference between the peak local SAR over the entire model and the peak local SAR at the voxels in the subset V_{sub} are reduced. With the local SAR constrained pulse design, the peak local SAR over the entire model is much closer to the lower bound than its upper bound.

Various embodiments described herein can be used alone or in combination with one another. The foregoing detailed description has described only a few of the many possible implementations of the present invention. For this reason, this detailed description is intended by way of illustration, and not by way of limitation.

1. A method of designing a parallel transmission radio frequency (RF) pulse for a magnetic resonance imaging (MRI) system, the method comprising:
compressing a model for a subject to be scanned by the MRI system into a plurality of virtual observation points within the model based on comparisons of peak sensitivity to local specific absorption rate (SAR); and
defining, with a processor, the parallel transmission RF pulse for antenna of the MRI system that minimizes a weighted average of local SAR values with an iterative procedure that optimizes a set of weighting factors for the plurality of virtual observation points to maximize the minimized weighted average.

2. The method of claim 1, wherein the iterative procedure is nested within an outer iterative procedure configured to minimize a peak local SAR value for the parallel transmission RF pulse being defined.

3. The method of claim 1, wherein defining the parallel transmission RF pulses comprises determining a direction to change each weighting factor that increases the minimized weighted average after each iteration of the iterative procedure.

4. The method of claim 1, further comprising, before implementing the iterative procedure, initializing the set of weighting factors to equal values that sum to unity.

5. The method of claim 1, wherein:
the model comprises a number of voxels;
the method further comprises calculating a spatial matrix for each voxel of the model, the spatial matrix being indicative of absorption sensitivity; and
compressing the model comprises defining an upper bound matrix for finding the virtual observation points as a sum of the spatial matrix of the virtual observation point and a global SAR matrix scaled by an overestimation factor.

6. The method of claim 5, wherein compressing the model further comprises selecting the overestimation factor.

7. The method of claim 5, wherein compressing the model further comprises iteratively evaluating the voxels to determine whether the absorption sensitivity of a respective one of the voxels is upper bounded by the absorption sensitivity of at least one previously evaluated voxel.

8. A method of applying a parallel transmission radio frequency (RF) pulse in a magnetic resonance imaging (MRI) system, the model being defined via a number of voxels, the method comprising:
calculating a spatial matrix for each voxel of a model for a subject to be scanned by the MRI system, the spatial matrix being indicative of absorption sensitivity;
designating a subset of the voxels as a plurality of virtual observation points for the model by iteratively evaluating the spatial matrices of the voxels to determine whether the absorption sensitivity of a respective one of the voxels is upper bounded by a global SAR-based overestimation of the absorption sensitivity of at least one previously evaluated voxel;
defining the parallel transmission RF pulse that minimizes a weighted average of local specific absorption rate (SAR) over the virtual observation points with an iterative procedure that optimizes a set of weighting factors for the weighted average to maximize the minimized weighted average of local SAR over the virtual observation points; and
transmitting the defined parallel transmission RF pulse.

9. The method of claim 8, wherein the iterative procedure is nested within an outer iterative procedure configured to minimize a peak local SAR value for the parallel transmission RF pulse being defined.

10. The method of claim 8, wherein defining the parallel transmission RF pulses comprises determining a direction to change each weighting factor that increases the minimized weighted average after each iteration of the iterative procedure.

11. The method of claim 8, further comprising, before implementing the iterative procedure, initializing the set of weighting factors to equal values that sum to unity.

12. The method of claim 8, wherein designating the subset of the voxels comprises defining an upper bound matrix for finding the virtual observation points as a sum of the spatial matrix of the virtual observation point and a global SAR matrix scaled by an overestimation factor that tunes the designating step.

13. The method of claim 12, wherein designating the subset of the voxels further comprises selecting the overestimation factor.

14. A magnetic resonance imaging (MRI) system comprising:
a data storage unit to store calibration data for a model for a subject to be scanned, the model having a number of voxels;
a coil array for transmitting a parallel transmission radio frequency (RF) pulse to the subject; and
a control system in communication with the data storage unit and the coil array;
wherein the control system is configured to design the parallel transmission RF pulse to control local specific absorption rate (SAR) based on the model, a model compression in which the model is compressed into a plurality of virtual observation points within the model based on comparisons of peak sensitivity to SAR, and an iterative procedure applied to pulses configured to minimize a weighted average of local SAR values, the iterative procedure being configured to optimize a set of weighting factors for the plurality of virtual observation points to maximize the minimized weighted average.

15. The magnetic resonance imaging (MRI) system of claim 14, wherein the iterative procedure is nested within an outer iterative procedure configured to minimize a peak local SAR value for the parallel transmission RF pulse being defined.

16. The magnetic resonance imaging (MRI) system of claim 14, wherein the control system is configured to determine a direction to change each weighting factor that increases the minimized weighted average after each iteration of the iterative procedure.

17. The magnetic resonance imaging (MRI) system of claim 14, wherein the control system is configured to initialize the set of weighting factors to equal values that sum to unity.

18. The magnetic resonance imaging (MRI) system of claim 14, wherein:
the model comprises a number of voxels;
the control system is configured to calculate a spatial matrix for each voxel of the model, the spatial matrix being indicative of absorption sensitivity; and
the control system is configured to define an upper bound matrix for finding the virtual observation points as a sum of the spatial matrix of the virtual observation point and a global SAR matrix scaled by an overestimation factor.

19. The magnetic resonance imaging (MRI) system of claim 18, wherein the control system is configured via user selection of the overestimation factor.

20. The magnetic resonance imaging (MRI) system of claim 18, wherein the control system is configured to iteratively evaluate the voxels to determine whether the absorption sensitivity of a respective one of the voxels is upper bounded by the absorption sensitivity of at least one previously evaluated voxel.
